(19) United States
(12) Patent Application Publication
(10) Pub. No.: US 2026/0011535 A1
(43) Pub. Date: Jan. 8, 2026

(54) MULTI-STAGE DYNAMIC VACUUM FEEDTHROUGH

(71) Applicant: Applied Materials, Inc., Santa Clara, CA (US)

(72) Inventors: BHARATH SWAMINATHAN, Livermore, CA (US); ANANTHA SUBRAMANI, San Jose, CA (US); FARZAD HOUSHMAND, Mountain View, CA (US); LUIS MARTINEZ, Mountain View, CA (US)

(21) Appl. No.: 18/766,299

(22) Filed: Jul. 8, 2024

(51) Int. Cl. H01J 37/32; H01L 21/683

(52) U.S. Cl. CPC H01J 37/32715; H01J 2237/2007; H01J 2237/20214; H01L 21/6831; H01L 21/6838

(57) ABSTRACT

Embodiments described herein relate to an apparatus that includes a first adapter that includes a plurality of first concentric separators, and a second adapter over the first adapter, where the second adapter includes a plurality of second concentric separators. In an embodiment, the second concentric separators are interleaved with the first concentric separators. In an embodiment, a sealing medium is provided between each of the plurality of first concentric separators, and the second concentric separators are inserted into a surface of the sealing medium.

### BACKGROUND

### 1) Field

Embodiments of the present disclosure pertain to the field of multi-stage dynamic vacuum feedthroughs.

### 2) Description of Related Art

In semiconductor processing operations a substrate is often secured to a chuck within a vacuum chamber. In some instances, the chuck is rotated in order to improve process uniformity across a surface of the substrate. For example, rotating the chuck (and the substrate) may result in a layer deposited on the substrate that has a more uniform thickness across the surface of the substrate. As such, product yields can be improved overall.

However, the chuck is typically coupled to a pedestal that provides electrical, liquid, and/or gas feedthroughs. A feedthrough may refer to an architecture that allows for the transition of a line (e.g., a gas line, a liquid line, an electrical line, etc.) from the atmospheric conditions outside of the chamber into the vacuum pressure within the chamber. As can be appreciated, passing lines across the pressure differential boundary can create problems with leakage of atmospheric gasses into the vacuum chamber. Existing architectures are designed to provide satisfactory feedthroughs when the chuck is stationary. However, when the chuck is rotated, the lines that pass across the pressure differential boundary create more complicated architectures that are susceptible to leakages.

### SUMMARY

Embodiments described herein relate to an apparatus that includes a first adapter that includes a plurality of first concentric separators, and a second adapter over the first adapter, where the second adapter includes a plurality of second concentric separators. In an embodiment, the second concentric separators are interleaved with the first concentric separators. In an embodiment, a sealing medium is provided between each of the plurality of first concentric separators, and the second concentric separators are inserted into a surface of the sealing medium.

Embodiments described herein relate to an apparatus that includes a shaft and a first adapter around the shaft. In an embodiment, the first adapter includes a plurality of first concentric separators. The apparatus may further include a second adapter around the shaft, where the second adapter includes a plurality of second concentric separators. In an embodiment, one of the first concentric separators is provided between each pair of adjacent second concentric separators. In an embodiment, the apparatus may further comprise a sealing medium between each pair of first concentric separators. In an embodiment, the second concentric separators extend into a surface of the sealing medium.

Embodiments described herein relate to an apparatus that includes a chamber and a chuck within the chamber. In an embodiment, a pedestal is coupled to the chuck and extends outside of the chamber. In an embodiment, the pedestal includes a first adapter that is interdigitated with a second adapter and a sealing medium between the first adapter and the second adapter. In an embodiment, the first adapter, the second adapter, and the sealing medium define a plurality of annular chambers between the first adapter and the second adapter. In an embodiment, the second adapter is mechanically coupled to the chuck, and the second adapter and the chuck are rotatable.

### BRIEF DESCRIPTION OF THE DRAWINGS

FIG. 1 is cross-sectional illustration of a chuck that is attached to a pillar with integrated utilities is shown, in accordance with an embodiment.

FIG. 2A is a cross-sectional illustration of a dynamic gas delivery feedthrough, in accordance with an embodiment.

FIG. 2B is a plan view illustration of a first adapter of a dynamic gas delivery feedthrough, in accordance with an embodiment.

FIG. 2C is a plan view illustration of a second adapter of a dynamic gas delivery feedthrough, in accordance with an embodiment.

FIG. 3 is a cross-sectional illustration of a portion of a vertically oriented dynamic gas delivery feedthrough, in accordance with an embodiment.

FIG. 4 is a perspective view illustration of a dynamic gas delivery feedthrough, in accordance with an embodiment.

FIG. 5A is a cross-sectional illustration of a dynamic gas delivery feedthrough, in accordance with an embodiment.

FIG. 5B is a zoomed in cross-sectional illustration of a portion of a dynamic gas delivery feedthrough, in accordance with an embodiment.

FIG. 6 is a cross-sectional illustration of a vacuum chamber with an integrated dynamic gas delivery feedthrough, in accordance with an embodiment.

FIG. 7 illustrates a block diagram of an exemplary computer system of a processing tool, in accordance with an embodiment of the present disclosure.

### DETAILED DESCRIPTION

Multi-stage dynamic vacuum feedthroughs are disclosed herein, in accordance with various embodiments. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, rotating chucks within vacuum chambers may result in difficulties with the design of utility feedthroughs. Particularly, leaks are more likely to be present as lines (e.g., gas lines, liquid lines, electrical lines, etc.) pass through the pressure differential boundary when the chuck is a rotating chuck. Existing solutions try to avoid such leaks through the use of certain sealing architectures. For example, one or more dynamic elastomeric seals or dynamic ferrofluidic seals may be used when rotating shafts are used to enable rotation of the chuck. However, such solutions are not without issue.

For example, elastomeric seals may not be suitable for high vacuum environments. That is, elastomeric seals may allow for relatively high leak rates when exposed to high pressure environments. Ferrofluidic seals may provide improved compatibility with high vacuum environment (i.e., by providing lower leak rates). However, ferrofluidic compositions may be reactive to certain chemistries used in the chamber to process the substrate or clean the clean the chamber. As such, the ferrofluidic seals may rapidly degrade and are not suitable for high volume manufacturing (HVM) environments. Full static seals and transfer rotation through a magnetic coupling has been another proposed solution. Unfortunately, such a dynamic seal does not allow for liquid feedthroughs. As such, only non-cooled and/or passively cooled chucks can benefit from such solutions. Additionally, the RF return faces additional challenges in the case of ferrofluidic feedthroughs.

Accordingly, embodiments disclosed herein include dynamic vacuum feedthroughs that rely on a low melting point (and low offgassing) sealing medium that is provided between a first adaptor and a second adaptor. In an embodiment, the first adaptor and the second adaptor may each comprise one or more concentric separators. The concentric separators of the first adaptor may be interdigitated (or interleaved) with the concentric separators of the second adaptor. The sealing medium may be dispensed into wells between the concentric separators of the first adaptor, and the concentric separators of the second adaptor may be inserted into the sealing medium. As such, a plurality of annular chambers may be generated. Each annular chamber may support a gas at a different pressure. Other embodiments may comprise pulling a vacuum in one or more of the annular chambers. Additionally, when the sealing medium comprises such a liquid metal material, the liquid metal acts as a conductor to allow for the RF return through the static shell.

In an embodiment, the rotation is enable by keeping the first adaptor stationary while allowing rotation of the second adaptor. The second adaptor may be mechanically coupled to the chuck in order to rotate the chuck as well. In some embodiments, the second adaptor is rotated by a drive belt or any other suitable rotational drive mechanism. In yet another embodiment, the annular separators in the feedthrough can be combined to form a single pool. In such an architecture, the separator may still provide a suitable barrier to define individual chambers. As such, the assembly may be more vertically compact compared to other solutions.

In an embodiment, the electrical and liquid feedthroughs may be provided through an opening within a central shaft. The central shaft may pass through holes at an axial center of the first adaptor and the second adaptor. In this way, the dynamic vacuum feedthrough enables vacuum feedthroughs for gasses, liquids, and/or electricity. Further, suitable sealing mediums described herein may provide excellent leakage protection, low outgassing, and high chemical resistance to processing gasses and/or cleaning gasses used within the vacuum chamber.

Furthermore, embodiments disclosed herein may be compatible with many existing processing tool architectures. That is, a pedestal with a dynamic vacuum feedthrough described herein may be substituted with existing pedestal architectures. As such, existing vacuum chambers that only enable stationary chucks can be simply converted into a vacuum chamber with a rotating chuck. The substitution may be made without the need for significant alterations to the design and/or function of the remainder of the vacuum chamber.

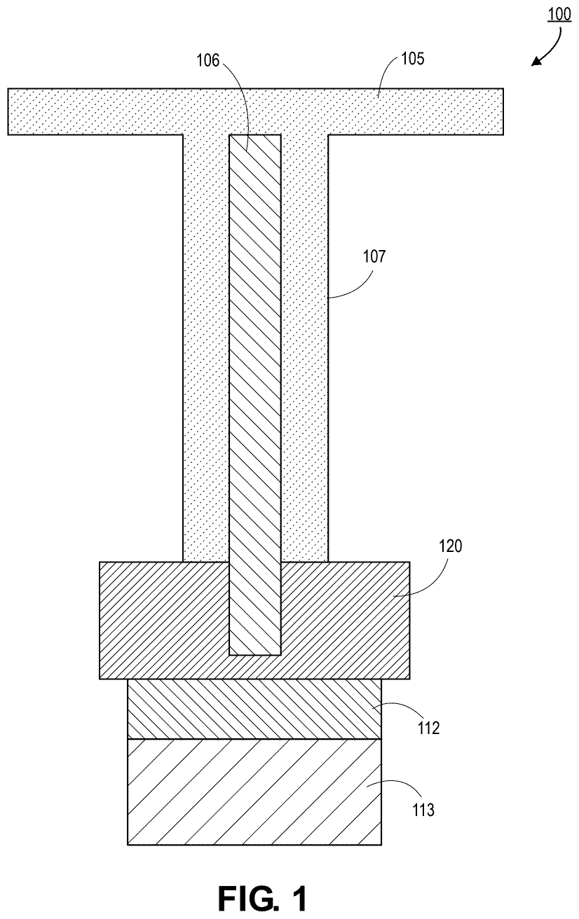

Referring now to FIG. 1, a cross-sectional illustration of a portion of a processing tool 100 is shown, in accordance with an embodiment. As shown, the processing tool 100 may comprise a chuck 105. The chuck 105 may be provided within a chamber (not shown), such as a vacuum chamber for plasma processing operations. The chuck 105 may be used to secure a substrate, such as a semiconductor wafer or the like. The chuck may be an electrostatic chuck (ESC), a vacuum chuck, or the like. In some embodiments, the chuck 105 may be coupled to one or more utilities from outside of the chamber. When the processing tool 100 comprises a chuck 105 that is configured to rotate, a dynamic feedthrough may be used in order to pass the one or more utilities lines (e.g., electrical, liquid, and/or gas) across the pressure differential barrier between an external atmospheric pressure and a vacuum pressure within the chamber.

For example, an ESC chuck 105 may be coupled to one or more RF, AC, and/or DC sources. For example, the electrical sources may be used to generate an electrostatic force to secure the substrate, heat the chuck, provide an RF bias to couple into the chamber to generate a plasma, operate one or more sensors, and/or the like. In an embodiment, the dynamic feedthrough for the one or more electrical lines may be provided with any suitable feedthrough architecture. For example, a roll ring module 112 may be used in some embodiments. The chuck 105 may also comprise one or more cooling channels that are fluidly coupled to a coolant fluid line. For example, the coolant fluid line may provide chilled water or other cooling fluid to the chuck. Any suitable fluid feedthrough module 113 may be used.

In an embodiment, one or more gas feed lines may be used to supply a gas to the chuck 105 and/or the chamber. For example, a helium gas line may be fed to the chuck 105 in order to control a backside gas pressure of a substrate during processing. In the case of a vacuum chuck 105, a gas line may also be used to pull a vacuum in order to generate the chucking force. In an embodiment, the gas feed line may be implemented with a multi-stage dynamic feedthrough 120.

In an embodiment, the dynamic feedthrough 120 allows for rotation without permitting the gas line to leak. In a particular embodiment, the dynamic feedthrough 120 may include a first adapter and a second adaptor. The adaptors may comprise interdigitated concentric separators that form annular chambers between the first adapter and the second adaptor. A sealing medium may be provided between the adaptors in order to fluidically isolate the different annular chambers from each other. As such, each annular chamber is capable of supporting a different pressure and/or containing a different gas. The number of annular chambers may match the desired number of gas lines needed for the processing tool. In an embodiment, the annular chambers may be oriented radially or vertically. A more detailed description of the dynamic feedthrough 120 for gas lines is described in greater detail herein.

In an embodiment, one or more of the gas lines, the liquid lines, and/or the electrical lines may pass through a conduit 106 that extends through the pedestal 107 that supports the chuck 105. While a single conduit 106 is shown, it is to be appreciated that any number of conduits may be used. In an embodiment, the pedestal 107 and the conduit 106 may rotate along with the chuck 105. For example, a rotating motor, (e.g., a belt drive or the like), may be used to drive the rotation of one or more of the chuck 105, the pedestal 107, and/or the conduit 106.

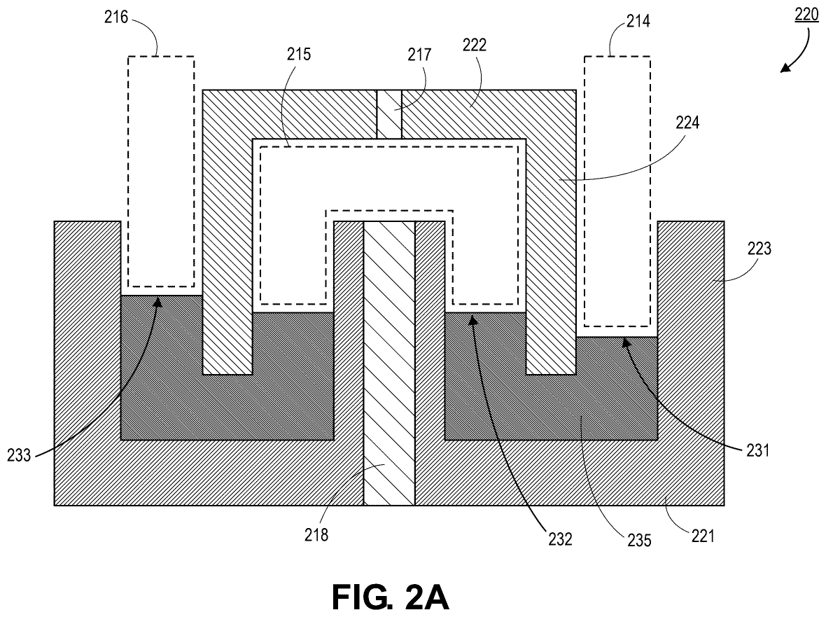

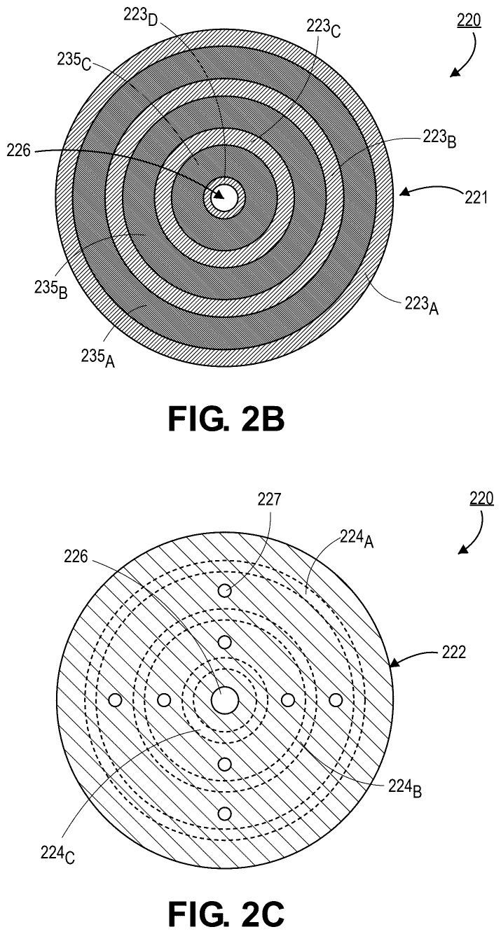

Referring now to FIG. 2A, a cross-sectional illustration of a portion of a dynamic feedthrough 220 for gas delivery is shown, in accordance with an embodiment. In an embodiment, the dynamic feedthrough 220 may comprise a first adaptor 221 and a second adaptor 222 that are stacked over each other. In an embodiment, the first adaptor 221 may be stationary, and the second adaptor 222 may be rotatable about an axial center of the second adaptor 222. In an embodiment, the first adaptor 221 may comprise a plate (e.g., a circular plate) with one or more concentric separators 223. For example, the concentric separators 223 may comprise a ring that extends up from the plate towards the second adaptor 222. For example, in FIG. 2A, a pair of concentric separators 223 are shown on the first adaptor 221. The outer concentric separator 223 is at an edge of the plate, and an inner concentric separator 223 is towards a center of the plate. The inner concentric separator 223 may surround a conduit 218 for supplying one or more electrical lines and/or liquid lines through an axial center of the dynamic feedthrough 220.

In an embodiment, the second adaptor 222 may comprise a plate and one or more concentric separators 224 that extend out from the plate towards the first adaptor 221. In an embodiment, the concentric separators 223 and the concentric separators 224 may be interdigitated with each other. Stated differently, neighboring concentric separators 223 may be separated from each other by a concentric separator 224. In an embodiment, sidewalls of the concentric separators 223 may at least partially overlap sidewalls of the concentric separators 224. In an embodiment, the second adaptor 222 may also comprise a rotary adaptor 217. The rotary adaptor 217 may be mechanically coupled to a rotating motor (not shown) in order to enable rotation of the second adaptor 222.

In an embodiment, a sealing medium 235 may be provided between each of the concentric separators 223 of the first adaptor 221. The sealing medium 235 may comprise a material that has a relatively low melting point. For example, a melting point of the sealing medium 235 may be approximately 150° C. or less. The use of a low melting point composition for the sealing medium 235 allows for the sealing medium 235 to be turned into a liquid during operation using a heating element (not shown) within one or both of the first adaptor 221 or the second adaptor 222. When the sealing medium 235 is in a liquid phase, the second adaptor 222 is free to rotate. Additionally, a sealing medium 235 that solidifies at room temperature may allow for easier maintenance since the sealing medium 235 will not leak or otherwise move during the maintenance. In some embodiments, the sealing medium 235 may comprise one or both of gallium or indium. Other embodiments may include a sealing medium 235 that remains fluid at room temperature. In such embodiments, the sealing medium 235 may also be a low vapor pressure material in order to prevent offgassing. The outgassing performance may be improved by actively cooling one or both of the first adaptor 221 or the second adaptor 222 (e.g., with fluidic cooling channels (not shown) or the like). For example, a low vapor pressure oil may be used as the sealing medium 235 in some embodiments.

In an embodiment, the sealing medium 235 and the concentric separators 223 and 224 may define one or more annular chambers 215 within the dynamic feedthrough 220. The annular chambers 215 may be fluidically isolated from each other. As such, gas that is provided to each annular chamber 215 will remain isolated from other gasses within the dynamic feedthrough 220. Additionally, the annular chambers 215 can be maintained at different pressures. In the embodiment shown in FIG. 2A, a single annular chamber 215 is shown as one example. The pressure in region 214 may be at atmospheric pressure, and the pressure at region 216 may be at a vacuum pressure. While not shown in FIG. 2A for simplicity, other features may surround the dynamic feedthrough 220 in order to separate the region 214 from the region 216. The pressure in the annular chamber 215 may be between the atmospheric pressure and the vacuum pressure. The pressure differentials may result in the sealing medium 235 having different surface heights. For example, surface 231 exposed to region 214 may have the lowest surface height, surface 232 within the annular chamber 215 may have the second lowest surface height, and the surface 233 exposed to region 216 may have the highest surface height. In an embodiment, a volume of the sealing medium 235 and the amount of overlap between the concentric separators 223 and 224 may be chosen to prevent the surfaces 231-233 from being compressed below a bottom of the concentric separators 224 or pulled above the concentric separators 223.

Referring now to FIGS. 2B and 2C, a pair of plan view illustrations of a first adaptor 221 (FIG. 2B) and a second adaptor (FIG. 2C) of the dynamic feedthrough is shown, in accordance with an embodiment.

Referring now to FIG. 2B, a plan view illustration of the first adaptor 221 of a dynamic feedthrough 220 is shown, in accordance with an embodiment. In an embodiment, the first adaptor 221 may comprise a plate (not visible) that has a circular shape. Though, other shapes may also be used in some embodiments. In an embodiment, a hole 226 may be provide through an axial center of the first adapter 221. The hole 226 may be used to accommodate electrical and/or fluid lines (not shown) that passes through the dynamic feedthrough 220. In an embodiment, a plurality of concentric separators 223 may extend up from the plate. In the illustrated embodiment, the concentric separators 223 are circular rings. Though, other shaped rings may also be used in some embodiments. In FIG. 2B, there are four concentric separators 223_{A}-223_{D}. Though, any number of concentric separators 223 may be used in other embodiments. In an embodiment, the outermost concentric separator 223_{A} is provided at an edge of the plate, and the innermost concentric separator 223_{D} is provided around the hole 226. The concentric separators 223_{A}-223_{D} may have a substantially uniform spacing. Other embodiments may include a non-uniform spacing between the concentric separators 223_{A}-223_{D}.

In an embodiment, sealing medium 235 may be provided over the plate between each pair of concentric separators 223. For example, three wells of sealing medium 235_{A}-235_{C} are shown in FIG. 2B. In an embodiment, the sealing medium 235 may be dispensed so that each well of the sealing medium 235_{A}-235_{C} has a uniform thickness. Though, in other embodiments, the sealing medium 235_{A}-235_{C} may have a non-uniform thickness.

Referring now to FIG. 2C, a plan view illustration of the second adaptor 222 of the dynamic feedthrough 220 is shown, in accordance with an embodiment. In an embodiment, the second adaptor 222 may comprise a plate that has a circular shape. Though, other shapes may also be used in some embodiments. In an embodiment, a hole 226 may be provide through an axial center of the second adapter 222. The hole 226 may be used to accommodate electrical and/or fluid lines (not shown) that passes through the dynamic feedthrough 220. In an embodiment, a plurality of concentric separators 224 may extend up from the plate. In the illustrated embodiment, the concentric separators 224 are circular rings. Though, other shaped rings may also be used in some embodiments. In FIG. 2C, there are three concentric separators 224_{A}-224_{C}. Though, any number of concentric separators 224 may be used in other embodiments. In an embodiment, the outermost concentric separator 224_{A} is spaced away from an edge of the plate, and the innermost concentric separator 224_{C} is spaced away from the hole 226. The concentric separators 224_{A}-224_{C} may have a substantially uniform spacing. Other embodiments may include a non-uniform spacing between the concentric separators 224_{A}-224_{C}. The concentric separators 224_{A}-224_{C} may be positioned so that the concentric separators 224 are interdigitated with the concentric separators 223 when the first adaptor 221 (FIG. 2B) is stacked over the second adaptor 222 (FIG. 2C).

In an embodiment, the second adaptor 222 may also comprise a plurality of holes 227. In an embodiment, one or more holes 227 may be provided between each of the concentric separators 224. The holes 227 allow for gas within the annular chambers between concentric separators 223 and 224 to flow out of the dynamic feedthrough 220.

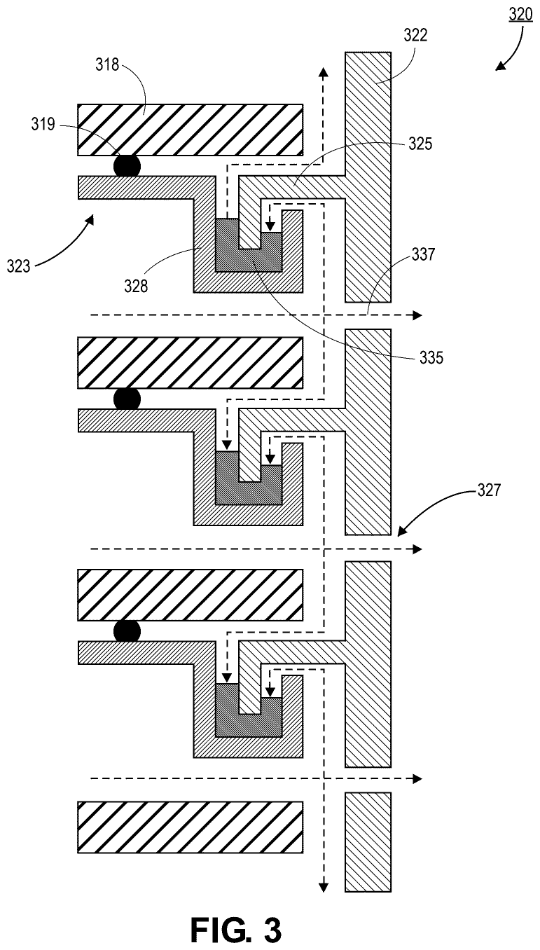

Referring now to FIG. 3, a vertically oriented dynamic feedthrough 320 is shown, in accordance with an embodiment. The use of a vertically oriented dynamic feedthrough 320 may save floor space around a processing tool compared to a radially oriented dynamic feedthrough, such as the feedthrough 220 described in greater detail herein. In an embodiment, the vertically oriented dynamic feedthrough 320 may operate similarly to the radially oriented dynamic feedthrough 220. For example, a plurality of stacked separators 323 of a first adaptor may interface with stacked separators 325 of a second adaptor 322.

In an embodiment, the stacked separators 323 may include a well region 328 to confine the sealing medium 335. The stacked separators 325 from the second adaptor may have an L-shape that extends into the sealing medium 335 of each well region 328. In an embodiment, the stacked separators 323 may be separated from each other by stacked layers 318 of the first adapter. An O-ring 319 or other seal may be provided between the stacked separators 323 and the stacked layers 318 in order to confine the gas in different chambers. For example, four chambers in a vertical stack are shown in FIG. 3. In an embodiment, holes 327 through the second adaptor 322 may be used to flow gas 337 out of the dynamic feedthrough 320. In an embodiment, the second adaptor 322 may be rotatable.

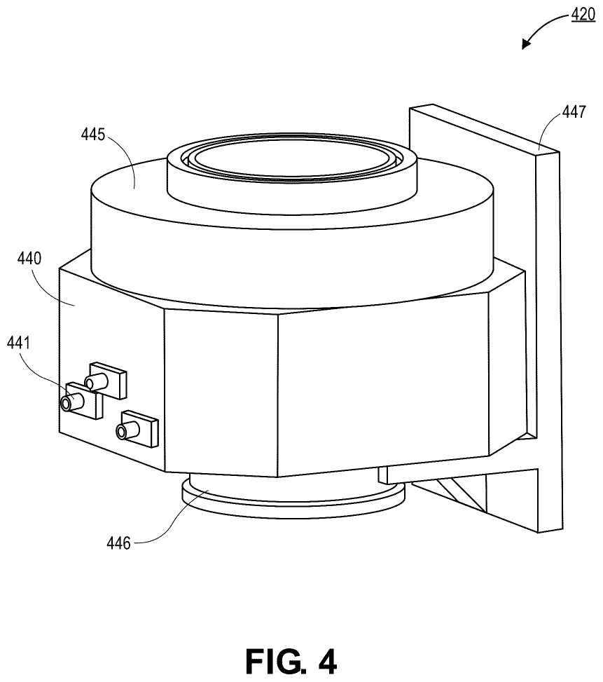

Referring now to FIG. 4, a perspective view illustration of a dynamic feedthrough 420 is shown, in accordance with an embodiment. In an embodiment, the dynamic feedthrough 420 may comprise an outer housing 440. The outer housing 440 may surround the first adaptor and the second adaptor (both not visible in FIG. 4). The first adaptor and the second adaptor may be similar to any of the first adaptors and second adaptors described in greater detail herein. In an embodiment, one or more gas inlets 441 may pass through a wall of the housing 440. In an embodiment, the inlets 441 may be fluidly coupled to different gas sources (not shown). In other embodiments, one or more of the inlets 441 may be coupled to a pump (not shown) in order to pull a vacuum within one or more of the annular chambers between the first adaptor and the second adaptor.

In an embodiment, a rotating motor 446 may be provided below the housing 440. The rotating motor 446 may be a belt drive motor or the like. In an embodiment, the rotating motor 446 may be mechanically coupled to the second adaptor in order to enable rotation of the second adaptor within the housing 440.

In an embodiment, a chamber interface module 445 may be provided over the housing 440. The chamber interface module 445 may allow for the dynamic feedthrough 420 to mount to any existing chamber (not shown). Accordingly, the existing chamber may not need any significant redesign in order to convert a stationary chuck into a rotating chuck when a dynamic feedthrough 420 is used. In an embodiment, the chamber interface module 445 may include a hole in order to pass gas lines, electrical lines, and/or liquid lines from the dynamic feedthrough 420 to the chuck (not shown). In an embodiment, the dynamic feedthrough 420 may also comprise a vertical lift adapter bracket 447 for positioning the dynamic feedthrough 420 relative to the chamber (not shown).

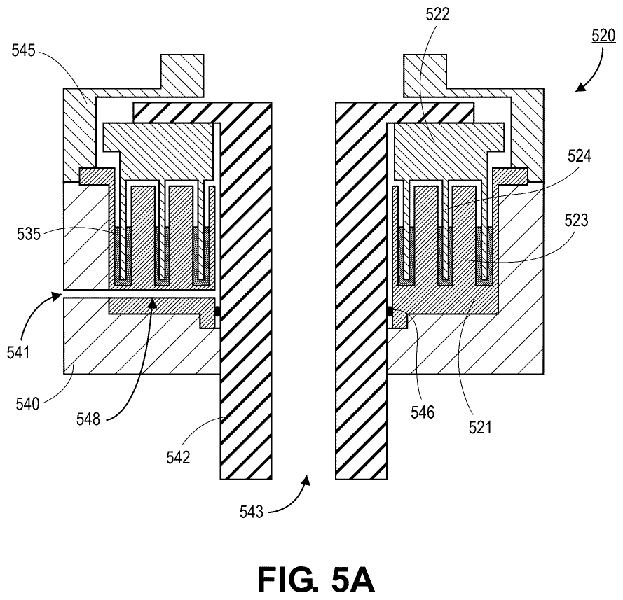

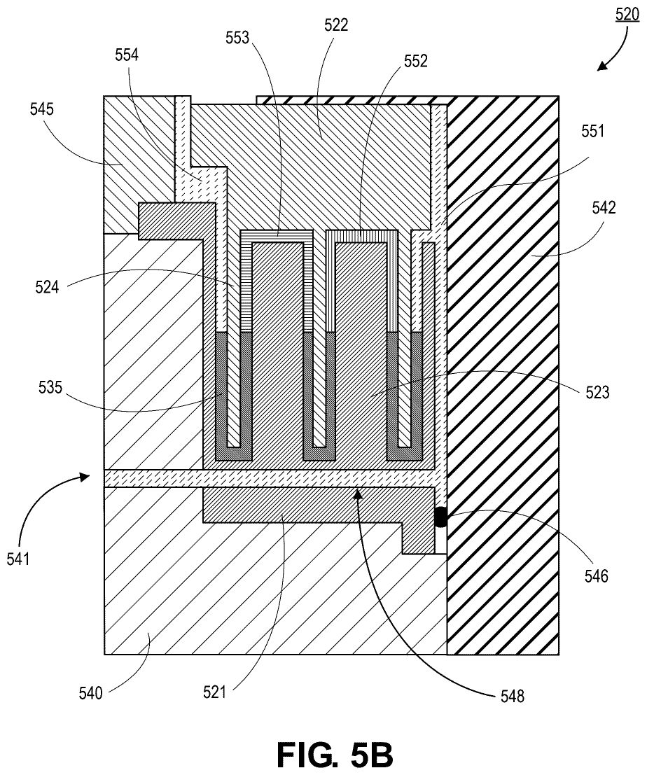

Referring now to FIG. 5A, a cross-sectional illustration of a dynamic feedthrough 520 is shown, in accordance with an embodiment. In an embodiment, the dynamic feedthrough 520 may comprise a housing 540. In an embodiment, a gas inlet 541 pass through the housing and fluidically couples with a channel 548 embedded within the first adaptor 521. In an embodiment, the first adaptor 521 may comprise a plurality of concentric separators 523 that extend up towards a second adaptor 522. In an embodiment, the second adaptor 522 comprises concentric separators 524 that extend down towards the first adaptor 521. In an embodiment, the concentric separators 523 may be interdigitated with the concentric separators 524. In an embodiment, the gaps between concentric separators 523 may be at least partially filled with a sealing medium 535. The sealing medium 535 may be similar to any of the sealing medium materials described in greater detail herein. The first adaptor 521 and the second adaptor 522 may be similar to any of the first adaptors or second adaptors described in greater detail herein. In an embodiment, a shaft 542 may pass through holes in the axial center of the first adapter 521 and the second adapter 522. In an embodiment, a hole 543 through the shaft 542 may be used to pass liquid lines and/or electrical lines through the dynamic feedthrough 520. In an embodiment, the shaft 542 may be mechanically coupled to the second adaptor 522. As such, rotation of the shaft 542 may induce rotation of the second adaptor 522. In an embodiment, an O-ring 546 or the like may seal the inner sidewall of the first adapter 521 against the outer surface of the shaft 542.

In an embodiment, a chamber interface module 545 may be provided over the housing 540. The inner surface of the chamber interface module 545 may be spaced apart from the outer edge of the second adaptor 522. As such, the outer edge of the second adaptor 522 may be maintained at the chamber vacuum pressure, as will be described in greater detail herein.

Referring now to FIG. 5B, a zoomed in cross-sectional illustration of a portion of the dynamic feedthrough 520 is shown, in accordance with an embodiment. FIG. 5B more clearly illustrates the plurality of annular chambers 551-554 that are provided by the dynamic feedthrough 520. In FIG. 5B, each of the annular chambers 551-554 are shown with different shadings in order to highlight the barriers between the annular chambers 551-554. Though, it is to be appreciated that the shadings may not indicate the presence of a solid material. Instead, the chambers 551-554 may be filled with gas (or maintained at a vacuum).

As shown, the inlet 541 that is coupled to channel 548 may be part of the first annular chamber 551. A second annular chamber 552 may be provided outside of the first annular chamber 551, a third annular chamber 553 may be provided outside of the second annular chamber 552, and a fourth annular chamber 554 may be provided outside of the third annular chamber 553. In an embodiment, each of the chambers 551-554 may be at least partially defined by a concentric separator 523, a concentric separator 524, and a sealing medium 535. In the illustrated embodiment, the first annular chamber 551 is the only annular chamber 551-554 that has a visible inlet. Though, it is to be appreciated that each of the annular chambers 551-554 may have an inlet that passes through the first adaptor 521 or the second adaptor outside of the plane of FIG. 5B.

In an embodiment, the annular chambers 551 may be arranged with decreasing pressures. For example, the first annular chamber 551 may have the highest pressure, and the fourth annular chamber 554 may have the lowest pressure. For example, the fourth annular chamber 554 may be fluidically coupled to the vacuum chamber interior so that the fourth annular chamber 554 may be maintained at a high vacuum.

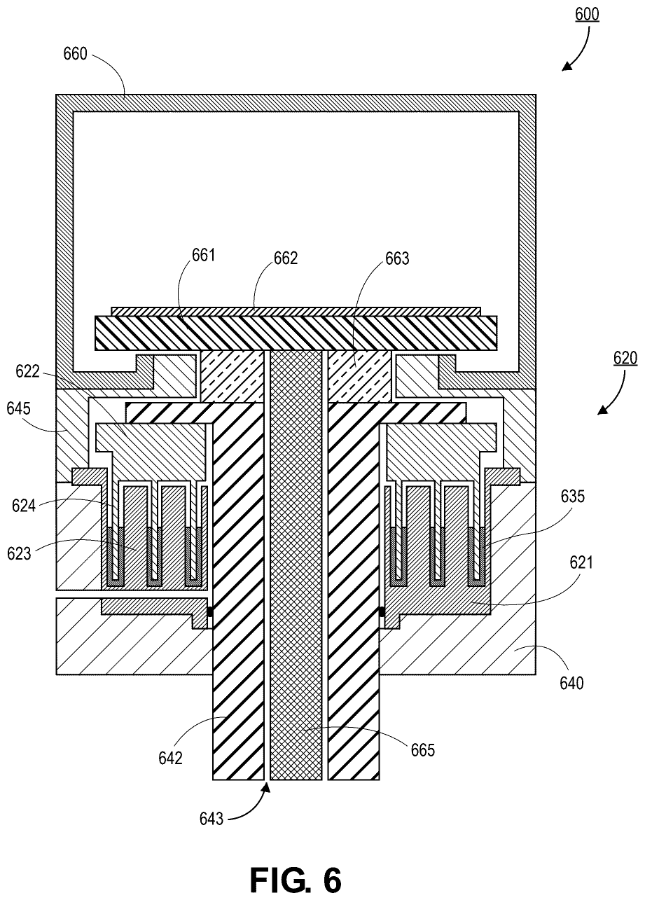

Referring now to FIG. 6, a cross-sectional illustration of a processing tool 600 is shown, in accordance with an embodiment. In an embodiment, the processing tool 600 may comprise a chamber 660 suitable for maintaining a vacuum. For example, the chamber 660 may be a chamber suitable for plasma processing or the like. In an embodiment, a chuck 661 for supporting a substrate 662 is provided in the chamber 660. In an embodiment, the chuck 661 may be rotatable. For example, the chuck 661 may be mechanical coupled to a rotatable shaft 642 by a mechanical coupler 663. In an embodiment, the shaft 642 may also be mechanically coupled to a rotatable second adaptor 622. In an embodiment, a conduit 665 may pass through a hole 643 in the shaft 642. The conduit 665 may provide electrical and/or liquid lines to the chuck 661.

In an embodiment, a dynamic feedthrough 620 is coupled to the chamber 660 by a chamber interface module 645. The chamber interface module 645 may be provided over a housing 640 that surrounds a first adaptor 621 and the second adaptor 622. In an embodiment, the dynamic feedthrough 620 may be similar to any of the dynamic feedthroughs described in greater detail herein. In an embodiment, the first adaptor 621 may comprise a plurality of annular separators 623 that are interdigitated with a plurality of annular separators 624 of the second adaptor 622. Sealing medium 635 may be provided between each of the annular separators 623 in order to define a plurality of annular chambers.

In the embodiments described in greater detail herein, the dynamic feedthroughs are described as being coupled to a rotating chuck within a vacuum chamber. However, it is to be appreciated that dynamic feedthroughs described herein may be used to enable rotation of any component within a vacuum chamber. For example, showerheads for gas distribution within a chamber may also be rotated in some processing tools. In such an embodiment, a dynamic feedthrough similar to any of the dynamic feedthroughs described herein may be coupled to the rotating showerhead.

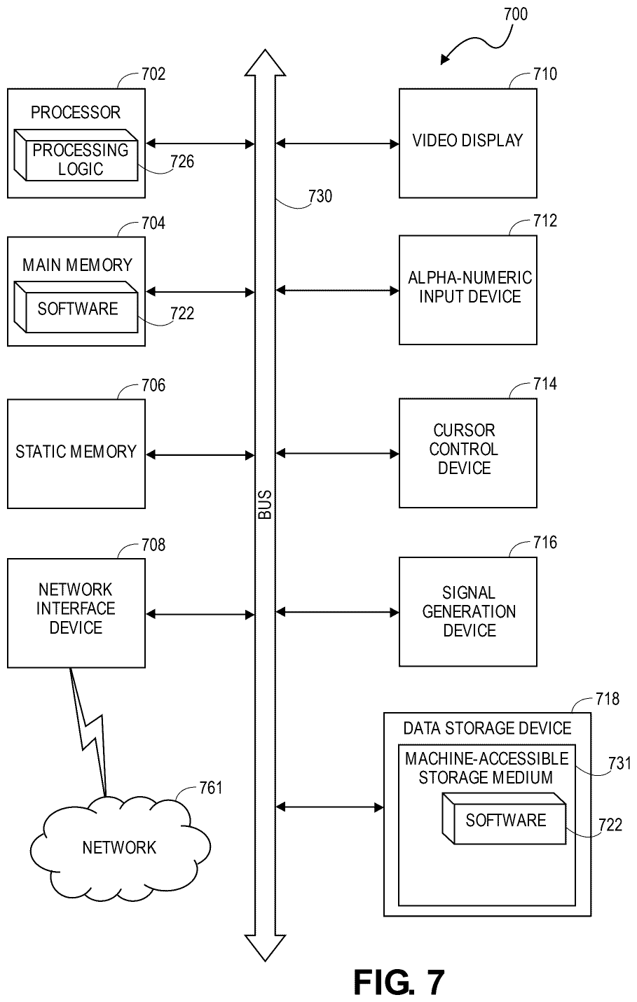

Referring now to FIG. 7, a block diagram of an exemplary computer system 700 of a processing tool is illustrated in accordance with an embodiment. In an embodiment, computer system 700 is coupled to and controls processing in a plasma processing chamber with a multi-stage dynamic vacuum feedthrough to supply one or more gasses to a chamber with a rotating chuck.

Computer system 700 may be connected (e.g., networked) to other machines in a Local Area Network (LAN), an intranet, an extranet, or the Internet. Computer system 700 may operate in the capacity of a server or a client machine in a client-server network environment, or as a peer machine in a peer-to-peer (or distributed) network environment. Computer system 700 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 700, the term “machine” shall also be taken to include any collection of machines (e.g., computers) that individually or jointly execute a set (or multiple sets) of instructions to perform any one or more of the methodologies described herein.

Computer system 700 may include a computer program product, or software 722, having a non-transitory machine-readable medium having stored thereon instructions, which may be used to program computer system 700 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 700 includes a system processor 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), etc.), and a secondary memory 718 (e.g., a data storage device), which communicate with each other via a bus 730.

System processor 702 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 702 may also be one or more special-purpose processing devices such as an application specific integrated circuit (ASIC), a field programmable gate array (FPGA), a digital signal system processor (DSP), network system processor, or the like. System processor 702 is configured to execute the processing logic 726 for performing the operations described herein.

The computer system 700 may further include a system network interface device 708 for communicating with other devices or machines. The computer system 700 may also include a video display unit 710 (e.g., a liquid crystal display (LCD), a light emitting diode display (LED), or a cathode ray tube (CRT)), an alphanumeric input device 712 (e.g., a keyboard), a cursor control device 714 (e.g., a mouse), and a signal generation device 716 (e.g., a speaker).

The secondary memory 718 may include a machine-accessible storage medium 731 (or more specifically a computer-readable storage medium) on which is stored one or more sets of instructions (e.g., software 722) embodying any one or more of the methodologies or functions described herein. The software 722 may also reside, completely or at least partially, within the main memory 704 and/or within the system processor 702 during execution thereof by the computer system 700, the main memory 704 and the system processor 702 also constituting machine-readable storage media. The software 722 may further be transmitted or received over a network 761 via the system network interface device 708. In an embodiment, the network interface device 708 may operate using microwave coupling, optical coupling, acoustic coupling, or inductive coupling.

While the machine-accessible storage medium 731 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

Thus, embodiments of the present disclosure include systems and methods for supplying one or more gasses to a vacuum chamber with a rotating chuck through a multi-stage dynamic vacuum feedthrough.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

What is claimed is:

1. An apparatus, comprising:
a first adapter, wherein the first adapter comprises a plurality of first concentric separators;
a second adapter over the first adapter, wherein the second adapter comprises a plurality of second concentric separators, wherein the plurality of second concentric separators are interleaved with the plurality of first concentric separators; and
a sealing medium between each of the plurality of first concentric separators, wherein the plurality of second concentric separators are inserted into a surface of the sealing medium.

2. The apparatus of claim 1, wherein the sealing medium has a melting temperature that is up to approximately 150° C.

3. The apparatus of claim 2, wherein the sealing medium comprises gallium and/or indium.

4. The apparatus of claim 1, wherein the sealing medium comprises oil.

5. The apparatus of claim 1, wherein the first adapter comprises a heater or a cooling channel.

6. The apparatus of claim 1, wherein the second adapter is rotatable.

7. The apparatus of claim 1, wherein the second adapter comprises one or more holes.

8. The apparatus of claim 1, further comprising:
a chuck coupled to the second adapter.

9. The apparatus of claim 1, further comprising:
a showerhead coupled to the second adapter.

10. The apparatus of claim 1, further comprising a hole through an axial center of the first adapter and the second adapter.

11. An apparatus, comprising:
a shaft;
a first adapter around the shaft, wherein the first adapter comprises a plurality of first concentric separators;
a second adapter around the shaft, wherein the second adapter comprises a plurality of second concentric separators wherein one of the plurality of first concentric separators is between each pair of adjacent second concentric separators; and
a sealing medium between each pair of first concentric separators, wherein the plurality of second concentric separators extend into a surface of the sealing medium.

12. The apparatus of claim 11, further comprising:
a plurality of channels within the first adapter, wherein each channel is fluidically coupled to one of a plurality of annular chambers between the first adapter and the second adapter, wherein each annular chamber is defined by at least a portion of a first concentric separator, at least a portion of a second concentric separator, and a surface of the sealing medium.

13. The apparatus of claim 12, further comprising a plurality of holes through the second adapter, wherein the plurality of holes are each fluidically coupled to one of the plurality of annular chambers.

14. The apparatus of claim 12, wherein each annular chamber is configured to be held at a different pressure.

15. The apparatus of claim 11, wherein the second adapter is rotatable.

16. The apparatus of claim 11, wherein the sealing medium comprises a material with a melting temperature below 150° C.

17. The apparatus of claim 11, wherein the second adapter is mechanically coupled to a chuck within a chamber.

18. An apparatus, comprising:
a chamber;
a chuck within the chamber;
a pedestal coupled to the chuck and extending outside of the chamber, wherein the pedestal comprises a first adapter that is interdigitated with a second adapter and a sealing medium between the first adapter and the second adapter, wherein the first adapter, the second adapter, and the sealing medium define a plurality of annular chambers between the first adapter and the second adapter, wherein the second adapter is mechanically coupled to the chuck, and wherein the second adapter and the chuck are rotatable.

19. The apparatus of claim 18, wherein one or both of the first adapter or the second adapter are temperature controlled.

20. The apparatus of claim 18, wherein the plurality of annular chambers are configured to be held at different pressures.
